(19) United States
(12) Patent Application Publication
(10) Pub. No.: US 2013/0032816 A1
(43) Pub. Date: Feb. 7, 2013

(54) HIGH ELECTRON MOBILITY TRANSISTORS AND METHODS OF MANUFACTURING THE SAME

(71) Applicants: In-jun Hwang, Hwaseong-si (KR); Hyuk-soon Choi, Hwaseong-si (KR); Jae-joon Oh, Seongnam-si (KR); Jong-bong Ha, Yongin-si (KR); Jong-seob Kim, Hwaseong-si (KR); Ki-ha Hong, Cheonan-si (KR); Jai-kwang Shin, Anyang-si (KR)

(72) Inventors: In-jun Hwang, Hwaseong-si (KR); Hyuk-soon Choi, Hwaseong-si (KR); Jae-joon Oh, Seongnam-si (KR); Jong-bong Ha, Yongin-si (KR); Jong-seob Kim, Hwaseong-si (KR); Ki-ha Hong, Cheonan-si (KR); Jai-kwang Shin, Anyang-si (KR)

(73) Assignee: SAMSUNG ELECTRONICS CO., LTD., Suwon-si (KR)

(21) Appl. No.: 13/431,397

(22) Filed: Mar. 27, 2012

(30) Foreign Application Priority Data
Aug. 1, 2011 (KR) 10-2011-0076576

(51) Int. Cl. H01L 29/20; H01L 21/335; H01L 29/778

(52) U.S. Cl. 257/76; 257/194; 438/172; 257/E29.246; 257/E29.089; 257/E21.403

(57) ABSTRACT

High electron mobility transistors (HEMTs) including a substrate and a HEMT stack on the substrate, the HEMT stack including a compound semiconductor layer that includes a 2-dimensional electron gas (2DEG), an upper compound semiconductor layer that has a polarization index higher than a polarization index of the compound semiconductor layer, and a source electrode, a drain electrode, and a gate that are disposed on the upper compound semiconductor layer. The substrate may be a nitride substrate that has a dielectric constant and a thermal conductivity higher than a dielectric constant and a thermal conductivity of a silicon substrate. The substrate may include an insulating layer that has a dielectric constant and a thermal conductivity higher than a dielectric constant and a thermal conductivity of the silicon substrate, a metal layer that is deposited on the insulating layer, and a plate that is attached to the metal layer.

### CROSS-REFERENCE TO RELATED APPLICATION

This application claims priority under 35 U.S.C. §119 to Korean Patent Application No. 10-2011-0076576, filed on Aug. 1, 2011, in the Korean Intellectual Property Office (KIPO), the entire contents of which is incorporated herein by reference.

### BACKGROUND

1. Field

Example embodiments relate to power devices and methods of manufacturing the same, and more particularly, to high electron mobility transistors (HEMTs) with excellent and/or improved heat dissipation functions and methods of manufacturing the HEMTs.

2. Description of the Related Art

A high electron mobility transistor (HEMT) is a power device that uses layers with different polarization indices and/or band gaps to induce a 2-dimensional electron gas (2DEG) used as a channel. A mobility of the HEMT is higher than a mobility of a general transistor.

A HEMT may include a wide band gap compound semiconductor. Accordingly, a breakdown voltage of the HEMT may be higher than a breakdown voltage of a general transistor. The breakdown voltage of the HEMT may increase in proportion to a thickness of a compound semiconductor layer including a 2DEG, for example, a gallium nitride (GaN) layer. However, a critical field of a silicon substrate on which the HEMT formed is lower than a critical field of the GaN layer. That is, a breakdown voltage of the silicon substrate of the HEMT is lower than a breakdown voltage of the GaN layer formed on the silicon substrate. Due to the silicon substrate, a breakdown voltage of the HEMT may be reduced.

In order to prevent a breakdown voltage of the HEMT from being reduced due to the silicon substrate, a sapphire substrate or a glass substrate may be used instead of a silicon substrate. However, if a sapphire or glass substrate is used, a thermal conductivity of the HEMT may be reduced, thereby making it difficult to use the HEMT as a high current device.

### SUMMARY

Example embodiments may provide high electron mobility transistors (HEMTs) with an increased or improved breakdown voltage, and excellent and/or improved thermal conductivity. Example embodiments may provide methods of manufacturing HEMTs with an increased or improved breakdown voltage, and excellent and/or improved thermal conductivity.

According to example embodiments, a HEMT includes a substrate and an HEMT stack that is formed on the substrate. The HEMT stack includes a compound semiconductor layer that includes a 2-dimensional electron gas (2DEG), an upper compound semiconductor layer that has a polarization index higher than a polarization index of the compound semiconductor layer, and a source electrode, a drain electrode, and a gate that are disposed on the upper compound semiconductor layer. The substrate is a nitride substrate that has a dielectric constant and a thermal conductivity higher than a dielectric constant and a thermal conductivity of a silicon substrate. The upper compound semiconductor layer may include a recess or an oxidized region. The HEMT may further include a depletion layer that is disposed between the upper compound semiconductor layer and the gate. The HEMT may further include a lightly doped drain (LDD) region that is disposed on the compound semiconductor layer between the gate and the drain electrode. The gate may be a p-metal gate or a nitride gate.

According to other example embodiments, a HEMT includes a substrate and a HEMT stack that is formed on the substrate. The HEMT stack includes a compound semiconductor layer that includes a 2DEG, an upper compound semiconductor layer that has a polarization index higher than a polarization index of the compound semiconductor layer, and a source electrode, a drain electrode, and a gate that are disposed on the upper compound semiconductor layer, The substrate includes a plurality of layers, and is a non-silicon substrate having a dielectric constant and a thermal electricity higher than a dielectric constant and a thermal electricity of a silicon substrate. The substrate may include a plate, a metal layer that is bonded to the plate, and a dielectric layer that is formed on the metal layer. The drain electrode and the metal layer may be connected to each other, and the plate may be a DBC plate.

According to still other example embodiments, a method of manufacturing a HEMT includes forming a HEMT stack on a substrate, attaching a carrier wafer to the HEMT stack, removing the substrate, attaching a nitride substrate, which has a dielectric constant and a thermal conductivity higher than a dielectric constant and a thermal conductivity of a silicon substrate, to a surface of the HEMT stack from which the substrate is removed, and removing the carrier wafer. The HEMT stack includes a compound semiconductor layer that includes a 2DEG, an upper compound semiconductor layer that has a polarization index higher than a polarization index of the compound semiconductor layer and a source electrode, a drain electrode, and a gate that are disposed on the upper compound semiconductor layer.

The nitride substrate may include an AlN substrate or a SiN substrate. The method may further include forming a recess or an oxidized region in the upper compound semiconductor layer. The method may further include a depletion layer between the upper compound semiconductor layer and the gate. The method may further include an LDD region on the compound semiconductor layer between the gate and the drain electrode. The gate may be a p-metal gate or a nitride gate. The nitride substrate may be attached directly at high temperature and high pressure or is attached by using anodic bonding using a high voltage.

According to yet other example embodiments, a method of manufacturing a HEMT includes forming a HEMT stack on a substrate, attaching a carrier wafer to the HEMT stack, removing the substrate, attaching a non-silicon substrate, which includes a plurality of layers and has a dielectric constant and a thermal conductivity higher than a dielectric constant and a thermal conductivity of a silicon substrate, to a surface of the HEMT stack from which the substrate is removed, and removing the carrier wafer. The HEMT stack includes a compound semiconductor layer that includes a 2DEG, an upper compound semiconductor layer that has a polarization index higher than a polarization index of the compound semiconductor layer, and a source electrode, a drain electrode, and a gate that are disposed on the upper compound semiconductor layer.

The attaching of the non-silicon substrate may include depositing a dielectric layer on a surface of the HEMT stack from which the substrate is removed, depositing a bonding metal layer to the dielectric layer, and bonding a plate to the metal layer. The plate may be any one of a Si plate, a DBC plate, a metal plate, and an AlN plate. The metal layer may be an alloy layer including one of Al, Cu, Au, and Si. The dielectric layer may include one of AlN, SiN, Al2O3, and SiO2. The method may further include connecting the drain electrode and the metal layer. The plate may be a DBC plate. The plate may be attached to the metal layer by using eutectic bonding.

According to at least one example embodiment, a high electron mobility transistor (HEMT) includes a nitride substrate with a dielectric constant and thermal conductivity greater than a dielectric constant and thermal conductivity of bulk silicon, and a HEMT stack on the nitride substrate, the HEMT stack including a first compound semiconductor layer including a 2-dimensional electron gas (2DEG), a second compound semiconductor layer on the first compound semiconductor layer, a polarization index of the second compound semiconductor layer greater than a polarization index of the first compound semiconductor layer, and a source electrode, a drain electrode, and a gate on the second compound semiconductor layer.

According to at least one example embodiment, a high electron mobility transistor (HEMT) includes a substrate including a plurality of layers, a dielectric constant and thermal conductivity of the substrate greater than a dielectric constant and thermal conductivity of bulk silicon, and a HEMT stack on the substrate, the HEMT stack including a first compound semiconductor layer including a 2-dimensional electron gas (2DEG), a second compound semiconductor layer on the first compound semiconductor layer, a polarization index of the second compound semiconductor layer greater than a polarization index of the first compound semiconductor layer, and a source electrode, a drain electrode, and a gate on the upper compound semiconductor layer.

According to at least one example embodiment, a method of manufacturing a high electron mobility transistor (HEMT) includes forming a HEMT stack on a substrate by forming a first compound semiconductor layer on the substrate, forming a second compound semiconductor layer with a greater polarization index than the first compound semiconductor layer such that a 2-dimensional electron gas (2DEG) is induced in the first semiconductor layer, forming a source electrode, a drain electrode, and a gate on the second compound semiconductor layer, attaching a carrier wafer to the HEMT stack, removing the substrate from a surface of the HEMT stack, attaching a nitride substrate with a dielectric constant and thermal conductivity greater than a dielectric constant and a thermal conductivity of bulk silicon to the surface, and removing the carrier wafer.

According to at least one example embodiment, a method of manufacturing a high electron mobility transistor (HEMT) includes forming a HEMT stack on a first substrate by forming a first compound semiconductor layer on the substrate, forming a second compound semiconductor layer with a greater polarization index than the first compound semiconductor layer such that a 2-dimensional electron gas (2DEG) is induced in the first compound semiconductor layer, forming a source electrode, a drain electrode, and a gate on the second compound semiconductor layer, attaching a carrier wafer to the HEMT stack, removing the first substrate from a surface of the HEMT stack, attaching a second substrate including a plurality of layers with a dielectric constant and thermal conductivity greater than a dielectric constant and a thermal conductivity of bulk silicon to the surface, and removing the carrier wafer.

According to at least one example embodiment, a semiconductor device includes a high electron mobility transistor on substrate, a dielectric constant and thermal conductivity of the substrate greater than a dielectric constant and thermal conductivity of bulk silicon.

### BRIEF DESCRIPTION OF THE DRAWINGS

Example embodiments will be more clearly understood from the following brief description taken in conjunction with the accompanying drawings. FIGS. 1-7 represent non-limiting, example embodiments as described herein.

FIG. 1 is a cross-sectional diagram illustrating high electron mobility transistors (HEMTs) according to example embodiments;

FIG. 2 is a cross-sectional diagram illustrating HEMTs according to other example embodiments;

FIGS. 3-5 are cross-sectional diagrams illustrating example HEMT stacks of the HEMTs illustrated in FIGS. 1 and 2;

FIG. 6 is a cross-sectional diagram illustrating methods of manufacturing a HEMT of FIG. 1 according to still other example embodiments; and

FIG. 7 is a cross-sectional diagram illustrating methods of manufacturing a HEMT of FIG. 2 according to further example embodiments.

It should be noted that these figures are intended to illustrate the general characteristics of methods, structure and/or materials utilized in certain example embodiments and to supplement the written description provided below. These drawings are not, however, to scale and may not precisely reflect the precise structural or performance characteristics of any given embodiment, and should not be interpreted as defining or limiting the range of values or properties encompassed by example embodiments. For example, the relative thicknesses and positioning of molecules, layers, regions and/or structural elements may be reduced or exaggerated for clarity. The use of similar or identical reference numbers in the various drawings is intended to indicate the presence of a similar or identical element or feature.

### DETAILED DESCRIPTION

Example embodiments will now be described more fully with reference to the accompanying drawings, in which example embodiments are shown. Example embodiments may, however, be embodied in many different forms and should not be construed as being limited to the embodiments set forth herein; rather, these embodiments are provided so that this disclosure will be thorough and complete, and will fully convey the concept of example embodiments to those of ordinary skill in the art. In the drawings, the thicknesses of layers and regions are exaggerated for clarity. Like reference numerals in the drawings denote like elements, and thus their description will be omitted.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Like numbers indicate like elements throughout. As used herein the term “and/or” includes any and all combinations of one or more of the associated listed items. Other words used to describe the relationship between elements or layers should be interpreted in a like fashion (e.g., “between” versus “directly between,” “adjacent” versus “directly adjacent,” “on” versus “directly on”).

It will be understood that, although the terms “first”, “second”, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises”, “comprising”, “includes” and/or “including,” if used herein, specify the presence of stated features, integers, steps, operations, elements and/or components, but do not preclude the presence or addition of one or more other features, integers, steps, operations, elements, components and/or groups thereof.

Example embodiments are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle may have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which example embodiments belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

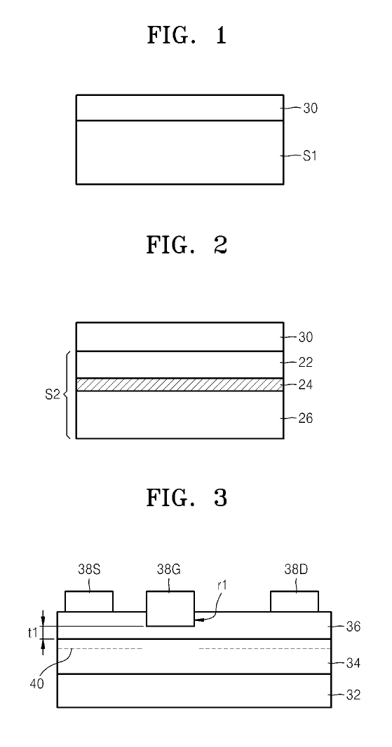

FIG. 1 is a cross-sectional diagram illustrating high electron mobility transistors (HEMTs) according to example embodiments. Referring to FIG. 1, a HEMT may include a first substrate S1 and a stack 30. The stack 30 may be on the first substrate S1. The stack 30 may include portions of the HEMT of FIG. 1 other than the first substrate S1. For example, the stack 30 may include a channel supply layer and a channel forming layer. The stack 30 may be referred to as “a HEMT stack 30” hereinafter.

According to example embodiments, the first substrate S1 may be a non-silicon substrate (e.g., not a bulk silicon substrate). According to at least one example embodiment, the first substrate S1 may be a non-metal plate. The first substrate S1 may be a plate with a high dielectric constant and high thermal conductivity. For example, the first substrate S1 may be a nitride and/or an oxide plate. The nitride plate may be, for example, aluminum nitride (AlN) and/or silicon nitride (SiN). The oxide plate may be, for example, Al₂O₃ and/or SiO₂. A thickness of the first substrate S1 may be about 1 μm to 100 μm. A breakdown voltage of the first substrate S1 may be greater (e.g., much greater) than a breakdown voltage of a silicon substrate (e.g., bulk silicon). If a HEMT includes a first substrate S1, a breakdown voltage of the HEMT may be increased, for example, as compared to a HEMT including a silicon substrate.

FIG. 2 is a cross-sectional diagram illustrating HEMTs according to other example embodiments. Referring to FIG. 2, a HEMT may include a second substrate S2 and a HEMT stack 30. The HEMT stack 30 may be on the second substrate S2. The second substrate S2 may include a plurality of layers. For example, the second substrate S2 may include a base plate 26, a bonding metal layer 24, and a dielectric layer 22 which may be stacked (e.g., sequentially stacked). The base plate 26 may be, for example, a silicon (Si) plate, a direct-bond copper (DBC) plate, a nitride plate, an oxide plate and/or a metal plate. The bonding metal layer 24 may be an alloy including, for example, aluminum (Al), copper (Cu), gold (Au) and/or silicon (Si). The bonding metal layer 24 may facilitate eutectic bonding. The dielectric layer 22 may include a high dielectric constant material of high thermal conductivity. For example, the dielectric layer 22 may include AlN, SiN, Al2O3 and/or SiO₂. The bonding metal layer 24 of the second substrate S2 and a drain electrode (not shown) of the HEMT stack 30 may be connected to each other, and the base plate 26 in this case may be a DBC plate.

FIGS. 3-5 are cross-sectional diagrams illustrating example HEMT stacks 30 of the HEMTs of FIGS. 1 and 2. Referring to FIG. 3, a HEMT stack 30 may include a buffer layer 32, a channel forming layer 34, and a channel supply layer 36 which may be stacked (e.g., sequentially stacked). The HEMT stack 30 may include a source electrode 38S, a drain electrode 38D and a gate 38G. The electrode 38S, the drain electrode 38D and the gate 38G may be on the channel supply layer 36. The buffer layer 32, the channel forming layer 34 and the channel supply layer 36 may be compound semiconductor layers. A structure of the buffer layer 32 may be a structure in which a nitride of boron (B), aluminum (Al), gallium (Ga) and/or indium (In), and/or a mixture thereof, may be stacked. For example, the buffer layer 32 may be an aluminum gallium nitride (AlGaN) layer.

The channel forming layer 34 and the channel supply layer 36 may be compound semiconductor layers with different band gaps and different polarization indices. For example, the channel forming layer 34 may be a GaN layer. The channel supply layer 36, which may be an upper compound semiconductor layer, may be a compound semiconductor layer with a band gap and a polarization index greater than a band gap and a polarization index of the channel forming layer 34. A structure of the channel supply layer 36 may be a structure in which a nitride of B, Al, Ga and/or In, and/or a mixture thereof, are stacked. For example, the channel supply layer 36 may be an AlGaN layer. Due to the channel supply layer 36, a 2-dimensional electron gas (2DEG) 40 may be generated in the channel forming layer 34 as a channel of the HEMT. The 2DEG 40 may be generated at an interface between the channel supply layer 36 and the channel forming layer 34. The channel supply layer 36 may be a layer for supplying a channel to the channel forming layer 34 or a layer for generating a channel in the channel forming layer 34. Because the 2DEG 40 may be generated in the channel forming layer 34, the channel forming layer 34 may be a layer in which a channel may be formed.

The source electrode 38S and the drain electrode 38D may be spaced apart from each other on the channel supply layer 36. The gate 38G may be between the source electrode 38S and the drain electrode 38D. The gate 38G may be spaced apart from the source and drain electrodes 38S and 38D. The gate 38G may be closer to the source electrode 38S than the drain electrode 38D. The channel supply layer 36 may include a recess r1 with a depth. The gate 38G may be in the recess r1. The recess r1 may be filled with the gate 38G or a part of the gate 38G. Due to the recess r1, a thickness t1 of a portion of the channel supply layer 36 under the gate 38G may be thinner than other portions of the channel supply layer 36. The thickness t1 of the portion of the channel supply layer 36 under the gate 38G may be, for example, about 1 to 20 nm.

Thicknesses of portions other than the portion of the channel supply layer 36 under the gate 38G may be greater than or equal to about 20 nm (e.g., about 20 nm to 100 nm). The recess r1 may be obtained by removing a part of the channel supply layer 36. An effect of the recess r1 on the channel forming layer 34 may be much smaller than the effects of portions other than the recess 11 on the channel forming layer 34. A 2DEG may not be generated in a portion of the channel forming layer 34 corresponding to the recess r1, for example, a portion of the channel forming layer 34 under the gate 38G. The HEMTs of FIGS. 1 and 2 may operate in an enhancement mode (referred to as an E-mode). A gate insulating film (not shown) may be between the gate 38G and the recess r1.

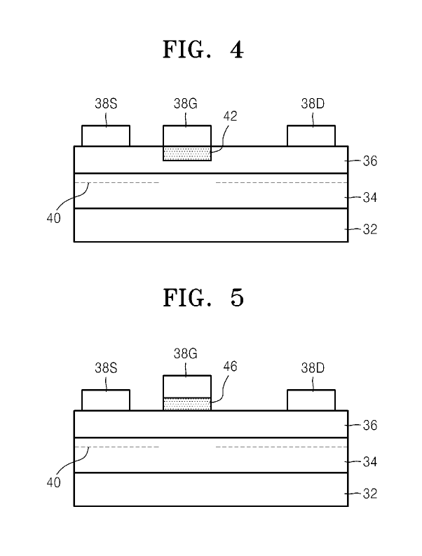

FIG. 4 is a cross-sectional diagram illustrating other example embodiments of a HEMT stack 30 of the HEMTs of FIGS. 1 and 2. Referring to FIG. 4, a HEMT stack 30 may include an oxidized region 42 in a channel supply layer 36. The oxidized region 42 may be a region, for example, processed with oxygen plasma. According to at least one example embodiment, a position of the oxidized region 42 may be the same as a position of the recess r1 of FIG. 3. A function of the oxidized region 42 may be the same as a function of the recess r1 of FIG. 3. A gate 38G may be on the oxidized region 42. A gate insulating film (not shown) may be between the gate 38G and the oxidized region 42.

FIG. 5 is a cross-sectional diagram illustrating further example embodiments of a HEMT stack 30 of the HEMTs of FIGS. 1 and 2. Referring to FIG. 5, a channel supply layer 36 may not include the recess r1 of FIG. 3 and the oxidized region 42 of FIG. 4. A channel depletion layer 46 may be between the channel supply layer 36 and the gate 38G. The 2DEG 40 under the channel depletion layer 46 may be depleted by the channel depletion layer 46. A function of the channel depletion layer 46 may be the same as a function of the recess r1 of FIG. 3 or the oxidized region 42 of FIG. 4. The channel depletion layer 46 may include a p-type semiconductor and/or a dielectric material. The channel depletion layer 46 may be, for example, a nitride layer including at least one of Al, In and Ga, and may be p-doped. The nitride layer may include, for example, GaN, indium nitride (InN), aluminum GaN (AlGaN), aluminum indium nitride (AlInN), indium GaN (InGaN) and/or aluminum indium GaN (AlInGaN).

Irrespective of whether the recess r1, the oxidized region 42, and the channel depletion layer 46 is included, or a combination of the same, as illustrated in FIGS. 3-5, a portion of the channel supply layer 36 contacting the gate 38G may be n-doped. Instead of the recess r1, the oxidized region 42, and the channel depletion layer 46 of FIGS. 3-5, the gate 38G may be a p-metal and/or a nitride. The p-metal may be, for example, nickel (Ni), iridium (Ir), platinum (Pt) and/or gold (Au). The nitride may be, for example, titanium nitride (TiN), tantalum nitride (TaN) and/or zirconium nitride (ZrN). In FIGS. 3-5, the recess r1, the oxidized region 42, and the channel depletion layer 46 may be provided, and the gate 38G may be a p-metal and/or a nitride.

A lightly doped drain (LDD) region (not shown) may be between the gate 38G and the drain electrode 38D on the channel forming layer 34 of the HEMT stack 30 illustrated in any of FIGS. 3-5. The LDD region may be connected to a region under the gate 38G of the channel forming layer 34. A 2DEG may be generated in the LDD region. A density of the 2DEG generated in the LDD region may be less than a density of a 2DEG generated in a portion where depletion does not occur. A HEMT stack 30 may not be limited to those described with reference to FIGS. 3-5. For example, in order to operate the HEMT in an E-mode and/or increase a breakdown voltage, the HEMT stack 30 may be variously configured. For example, a density of a 2DEG may be increased by a channel enhancement layer between the source and drain electrodes 38S and 38D of the HEMT stack 30.

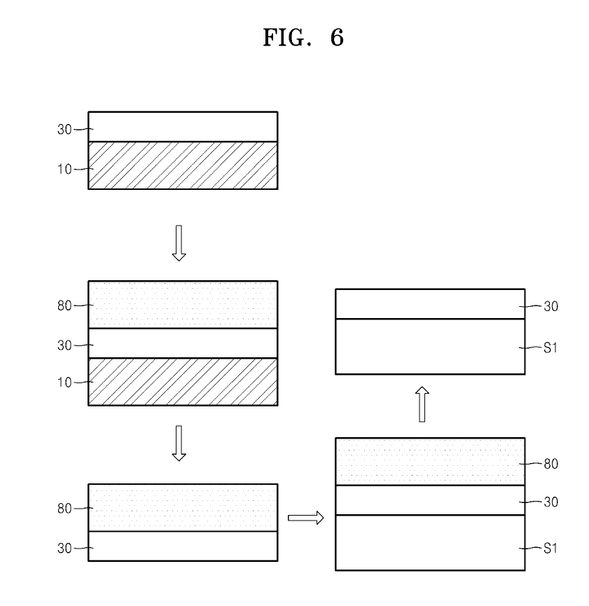

FIG. 6 is a cross-sectional diagram illustrating methods of manufacturing a HEMT of FIG. 1 according to still other example embodiments. The same elements as those of FIGS. 1-5 may be denoted by the same reference numerals, and an explanation thereof may not be provided. Referring to FIG. 6, a HEMT stack 30 may be formed on a substrate 10. The substrate 10 may be, for example, a silicon substrate. A method of forming the HEMT stack 30 may be easily understood from a configuration of the HEMT stack illustrated in each of FIGS. 3-5. A buffer layer 32 may be formed on a substrate 10. A channel forming layer 34 may be formed on the buffer layer 32. A channel supply layer 36 may be formed on the channel forming layer 34. The buffer layer 32, the channel forming layer 34 and the channel supply layer 36 may be sequentially stacked on the substrate 10.

A recess r1 may be formed in the channel supply layer 36. Source and drain electrodes 38s and 38D may be formed on the channel supply layer 36. A gate 38G may be formed by filling the recess r1 and the HEMT stack 30 may be formed. A Si carrier wafer 80 may be attached to the HEMT stack 30. The Si carrier wafer 80 may be attached to the HEMT stack 30 by using, for example, benzocyclobutene (BCB). The substrate 10 may be removed. The first substrate 51 may be attached at a location where the substrate 10 was removed. In this case, the HEMT stack 30 and the first substrate S1 may be directly bonded to each other, for example, at high temperature and high pressure. According to at least one example embodiment, the HEMT stack 30 and the first substrate S1 may be bonded to each other by using, for example, anodic bonding using a high voltage. The Si carrier wafer 80 may removed, for example, after the first substrate S1 is attached to the HEMT stack 30, to form the HEMT of FIG. 1.

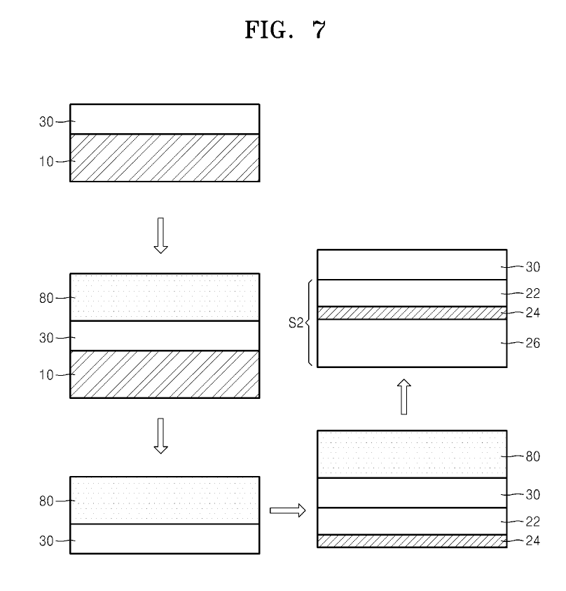

FIG. 7 is a cross-sectional diagram illustrating methods of manufacturing the HEMT of FIG. 2 according to further example embodiments. The same elements as those of FIGS. 1-5 may be denoted by the same reference numerals, and an explanation thereof may not be provided. Referring to FIG. 7, a Si carrier wafer 80 may be attached and the substrate 10 may be removed according to the method described above with reference to FIG. 6. A dielectric layer 22 with a high dielectric constant and high thermal conductivity may be deposited on an exposed surface of a HEMT stack 30 at a location where the substrate 10 was removed. A bonding metal layer 24 may be deposited on a bottom surface of the dielectric layer 22. The dielectric layer 22 and the bonding metal layer 24 may be sequentially deposited by using, for example, chemical vapor deposition (CVD), and/or other well-known methods. The bonding metal layer 24 may be provided for eutectic bonding. The plate 26 may be attached to the bonding metal layer 24. The bonding metal layer 24 and the plate 26 may be attached to each other via eutectic bonding. The dielectric layer 22, the bonding metal layer 24, and the plate 26 may constitute a second substrate S2. The Si carrier wafer 80 may be removed, for example, after the plate 26 is attached to the bonding metal layer 24, to form a HEMT of FIG. 2.

While example embodiments have been particularly shown and described, it will be understood by one of ordinary skill in the art that variations in form and detail may be made therein without departing from the spirit and scope of the claims.

What is claimed is:

1. A high electron mobility transistor (HEMT), comprising:
a nitride substrate with a dielectric constant and thermal conductivity greater than a dielectric constant and thermal conductivity of bulk silicon; and
a HEMT stack on the nitride substrate, the HEMT stack including
a first compound semiconductor layer including a 2-dimensional electron gas (2DEG),
a second compound semiconductor layer on the first compound semiconductor layer, a polarization index of the second compound semiconductor layer greater than a polarization index of the first compound semiconductor layer, and
a source electrode, a drain electrode, and a gate on the second compound semiconductor layer.

2. The HEMT of claim 1, wherein the nitride substrate is one of an aluminum nitride (AlN) substrate and a silicon nitride (SiN) substrate.

3. The HEMT of claim 1, wherein the second compound semiconductor layer includes at least one of a recess region and an oxidized region.

4. The HEMT of claim 1, further comprising:
a depletion layer between the second compound semiconductor layer and the gate.

5. The HEMT of claim 1, further comprising:
a lightly doped drain (LDD) region on the compound semiconductor layer between the gate and the drain electrode.

6. The HEMT of claim 1, wherein the gate is at least one of a p-metal gate and a nitride gate.

7. A high electron mobility transistor (HEMT), comprising:
a substrate including a plurality of layers, a dielectric constant and thermal conductivity of the substrate greater than a dielectric constant and thermal conductivity of bulk silicon; and
a HEMT stack on the substrate, the HEMT stack including
a first compound semiconductor layer including a 2-dimensional electron gas (2DEG);
a second compound semiconductor layer on the first compound semiconductor layer, a polarization index of the second compound semiconductor layer greater than a polarization index of the first compound semiconductor layer; and
a source electrode, a drain electrode, and a gate on the upper compound semiconductor layer.

8. The HEMT of claim 7, wherein
the plurality of layers is at least three layers, and
the at least three layers include a plate, a metal layer bonded to the plate, and a dielectric layer on the metal layer.

9. The HEMT of claim 8, wherein the plate includes one of a silicon (Si) plate, a direct-bonded copper (DBC) plate, a metal plate, and an aluminum nitride (AlN) plate.

10. The HEMT of claim 8, wherein the metal layer includes one of aluminum (Al), copper (Cu), gold (Au), and silicon (Si).

11. The HEMT of claim 8, wherein the dielectric layer includes one of AlN, SiN, Al2O3, and SiO2.

12. The HEMT of claim 8, wherein
the drain electrode and the metal layer are connected to each other, and
the plate is a direct-bonded copper (DBC) plate.

13. The HEMT of claim 7, wherein the second compound semiconductor layer includes at least one of a recess region and an oxidized region.

14. The HEMT of claim 7, further comprising:
a depletion layer between the second compound semiconductor layer and the gate.

15. The HEMT of claim 7, further comprising:
a lightly doped drain (LDD) region on the first compound semiconductor layer between the gate and the drain electrode.

16. The HEMT of claim 7, wherein the gate is one of a p-metal gate and a nitride gate.

17. A method of manufacturing a high electron mobility transistor (HEMT), the method comprising:
forming a HEMT stack on a substrate by
forming a first compound semiconductor layer on the substrate,
forming a second compound semiconductor layer with a greater polarization index than the first compound semiconductor layer such that a 2-dimensional electron gas (2DEG) is induced in the first semiconductor layer,
forming a source electrode, a drain electrode, and a gate on the second compound semiconductor layer;
attaching a carrier wafer to the HEMT stack;
removing the substrate from a surface of the HEMT stack;
attaching a nitride substrate with a dielectric constant and thermal conductivity greater than a dielectric constant and a thermal conductivity of bulk silicon to the surface; and
removing the carrier wafer.

18. The method of claim 17, wherein the nitride substrate includes at least one of AlN and SiN.

19. The method of claim 17, further comprising:
forming at least one of a recess and an oxidized region in the second compound semiconductor layer.

20. The method of claim 17, further comprising:
forming a depletion layer between the second compound semiconductor layer and the gate.

21. The method of claim 17, further comprising:
forming a lightly doped drain (LDD) region on the first compound semiconductor layer between the gate and the drain electrode.

22. The method of claim 17, wherein the gate is one of a p-metal gate and a nitride gate.

23. The method of claim 17, wherein the attaching a nitride substrate includes one of
directly attaching the nitride substrate at high temperature and high pressure, and
attaching the nitride substrate using high voltage anodic bonding.

24. A method of manufacturing a high electron mobility transistor (HEMT), the method comprising:
forming a HEMT stack on a first substrate by
forming a first compound semiconductor layer on the substrate,
forming a second compound semiconductor layer with a greater polarization index than the first compound semiconductor layer such that a 2-dimensional electron gas (2DEG) is induced in the first compound semiconductor layer,
forming a source electrode, a drain electrode, and a gate on the second compound semiconductor layer;
attaching a carrier wafer to the HEMT stack;
removing the first substrate from a surface of the HEMT stack;
attaching a second substrate including a plurality of layers with a dielectric constant and thermal conductivity greater than a dielectric constant and a thermal conductivity of bulk silicon to the surface; and
removing the carrier wafer.

25. The method of claim 24, wherein the attaching a second substrate includes
depositing a dielectric layer on the surface of the HEMT stack;
depositing a bonding metal layer on the dielectric layer; and
bonding a plate to the metal layer.

26. The method of claim 25, wherein the plate is one of a Si plate, a direct-bonded copper (DBC) plate, a metal plate, and an AlN plate.

27. The method of claim 25, wherein the metal layer is an alloy layer including one of Al, Cu, Au, and Si.

28. The method of claim 25, wherein the dielectric layer includes one of AlN, SiN, Al2O3, and SiO2.

29. The method of claim 25, further comprising:
connecting the drain electrode and the metal layer,
wherein the plate is a direct-bonded copper (DBC) plate.

30. The method of claim 25, wherein the plate is attached to the metal layer by eutectic bonding.
